(19) United States
(12) Patent Application Publication
(10) Pub. No.: US 2025/0076088 A1
(43) Pub. Date: Mar. 6, 2025

(54) WIRELESS SENSOR DEVICE

(71) Applicant: LS ELECTRIC CO., LTD., Anyang-si, Gyeonggi-do (KR)

(72) Inventors: Ki Hyeon KIM, Anyang-si, Gyeonggi-do (KR); Hyun Wook LEE, Anyang-si, Gyeonggi-do (KR); Min Kyu SEO, Anyang-si, Gyeonggi-do (KR); Woo Young CHOI, Anyang-si, Gyeonggi-do (KR)

(21) Appl. No.: 18/727,773

(22) PCT Filed: Jan. 2, 2023
(86) PCT No.: PCT/KR2023/000034

§ 371 Date: Jul. 10, 2024

(30) Foreign Application Priority Data
Jan. 10, 2022 (KR) 10-2022-0003143

(51) Int. Cl. G01D 11/00

(52) U.S. Cl. CPC G01D 11/00

(57) ABSTRACT

A wireless sensor device is disclosed. The wireless sensor device according to an aspect of the present disclosure may comprise: a sensor module which is placed adjacent to a part of an external member and is configured to sense information on a state of the member; a power module which is placed adjacent to another part of the external member to be physically spaced apart from the sensor module, and is configured to be electrically connected to the sensor module to transfer power to the sensor module; and a conducting wire member which is electrically connected to each of the sensor module and the power module to conduct the power.

### CROSS-REFERENCE TO RELATED APPLICATIONS

This application is the National Stage filing under 35 U.S.C. 371 of International Application No. PCT/KR2023/000034, filed on Jan. 2, 2023, which claims the benefit of earlier filing date and right of priority to Korean Application No. 10-2022-0003143, filed on Jan. 10, 2022, the contents of which are all hereby incorporated by reference herein in their entirety.

### FIELD

The present disclosure relates to a wireless sensor device, and more particularly, to a wireless sensor device having a structure in which a power supplying member and an information detecting member are disposed apart from each other.

### BACKGROUND

A circuit breaker is a device that is energizably connected to each of an external power source and a load to permit or prevent an electrically conductive state between the external power source and the load. When abnormal current such as overcurrent is introduced from the external power source into the circuit breaker, the circuit breaker performs a cut-off operation (trip operation) and prevents the electrically conductive state between the external power source and the load.

A circuit breaker includes various components. As the circuit breaker operates, the components operate, and heat is generated. Also, even when abnormal current is applied from an external power source, excessive heat may be generated in each component of the circuit breaker.

When the generated heat is retained in the circuit breaker for a predetermined amount of time or more, there is a concern that each component of the circuit breaker may be damaged. Accordingly, a circuit breaker typically has a detection device for measuring the temperature of the inside or outside.

Also, for normal operation of a circuit breaker, it may be preferable to collect various pieces of information other than temperature that relate to the circuit breaker itself and the surrounding environment such as humidity level, vibration, and intensity. The collected information may be transferred to a manager terminal and utilized by a manager as a basis for determining an operational state of the circuit breaker.

A sensor may be provided as a means for collecting various pieces of information. The sensor includes a detector for collecting various pieces of information and a communication means for transferring the detected information to the manager terminal. Further, the sensor is typically configured to further include a power source that supplies power necessary for the detector and the communication means to operate.

In the case of the communication means, a separate conducting wire member is required to connect the sensor and the manager terminal in a wired form. When the sensor and the manager terminal are connected by the conducting wire member, an issue related to a wiring structure occurs. Thus, nowadays, sensors that can exchange information with manager terminals in a wireless manner are widely used.

Limitations on installation positions are relatively reduced for sensors that operate in a wireless manner, as compared to sensors that operate in a wired manner. Specifically, in a case in which a sensor operating in a wired manner is installed on a member to which high voltage is applied, there is a concern that insulation performance of an electric device including the member may be degraded. Thus, in the above case, it is more preferable to install a sensor operating in a wireless manner.

However, the sensor operating in a wireless manner is not able to receive power necessary for operation from the outside and thus is configured to include a separate power supply means such as a battery. Accordingly, since the overall weight and volume of the sensor excessively increase due to the weight and volume of the battery itself, limitations may occur in terms of locations and manners of installation.

Further, the operating efficiency of the battery may change according to external environmental factors such as temperature. In particular, when the battery is located in a circuit breaker in which high-temperature heat is generated, a problem of accidents may occur.

Therefore, it is difficult for the sensor operating in a wireless manner to be accurately disposed at a position at which measurement of information such as temperature is required.

Korean Patent Registration No. 10-1775611 discloses a wireless temperature sensor module. Specifically, a wireless temperature sensor module that is attached to a boiler, is able to monitor the temperature and heat flux of a boiler tube, and has a self-power supply means using a thermoelectric element is disclosed.

However, in the wireless temperature sensor module disclosed in the related art document, the thermoelectric element and a sensor for detecting a state are coupled to each other and integrally provided. That is, in the related art document, state detection and power acquisition should be performed at the same position, and ways to configure a state detection target point and a power acquisition point differently are not presented.

Korean Patent Registration No. 10-1979631 discloses a wireless temperature detection apparatus. Specifically, a wireless temperature detection apparatus that is driven with a magnetic energy harvesting coil as a power source and is able to detect the temperature of a column or the like around which the coil is wound and transmit the detected temperature to a reception module is disclosed.

However, in the wireless temperature sensor module disclosed in the related art document, a thermoelectric element and a temperature sensing module are integrally formed. That is, in the wireless temperature sensor module disclosed in the related art document, it is assumed that a power supplying member and a temperature detecting member are disposed at the same point. Therefore, the related art document does not disclose ways to decrease the size of the module itself and improve a degree of freedom in terms of installation location.
Korean Patent Registration No. 10-1775611 (Sep. 7, 2017)
Korean Patent Registration No. 10-1979631 (May 17, 2019)

### SUMMARY

The present disclosure is for addressing the above problems and is directed to providing a wireless sensor device having a structure that can reduce the volume of space occupied thereby.

The present disclosure is also directed to providing a wireless sensor device having a structure that can improve a degree of freedom of arrangement of a component for information detection and a component that supplies power.

The present disclosure is also directed to providing a wireless sensor device having a structure that can prevent damage to a component that supplies power.

The present disclosure is also directed to providing a wireless sensor device having a structure that can supply power in various manners to correspond to various environments.

The present disclosure is also directed to providing a wireless sensor device having a structure that facilitates maintenance and repair.

The objects of the present disclosure are not limited to the above-mentioned objects, and other objects that are not mentioned will be able to be clearly understood by those skilled in the art to which the present disclosure pertains from the following description.

One aspect of the present disclosure provides a wireless sensor device including: a sensor module disposed adjacent to one portion of an external member and configured to detect information on a state of the external member: a power module disposed adjacent to another portion of the external member to be physically spaced apart from the sensor module and configured to be electrically conductive with the sensor module to transmit power to the sensor module; and a conducting wire member configured to be electrically conductive with each of the sensor module and the power module to transmit the power.

Here, the sensor module and the power module may be removably coupled to each other.

Also, the power module may include a coil member configured to generate the power in a magnetic field energy harvesting manner using a change in a magnetic field formed therein.

Here, a band made of a ferromagnetic substance may pass through the coil member.

Also, the power module may include: a power housing in which a space accommodating the coil member is formed: a power printed circuit board (PCB) accommodated in the space of the power housing and configured to be electrically conductive with the coil member; and a power connector accommodated in the space of the power housing and configured to be electrically conductive with the power PCB, receive the power generated by the coil member, and be coupled to and electrically conductive with the conducting wire member to transmit the received power to the sensor module.

Here, the power module may include a battery pack configured to be charged by an external power source, store the power, and transmit the stored power to the sensor module.

Also, the power module may include: a power housing in which a space accommodating the battery pack is formed; and a power connector accommodated in the space of the power housing and configured to be electrically conductive with the battery pack, receive the power stored in the battery pack, and be coupled to and electrically conductive with the conducting wire member to transmit the received power to the sensor module.

Here, the battery pack may be withdrawably accommodated in the space of the power housing.

Also, the power module may include a thermoelectric element configured to generate power using a temperature difference between the one portion of the external member and a space where the external member is located.

Also, the power module may include a heat dissipation member coupled to one surface facing the space where the external member is located among surfaces of the thermoelectric element and configured to cool the one surface of the thermoelectric element.

Here, the heat dissipation member may include a plurality of fins formed to extend in a direction opposite to the one surface of the thermoelectric element and a plurality of spaces formed by the plurality of fins being spaced apart from each other.

Also, the power module may include a power connector configured to be electrically conductive with the thermoelectric element, receive the power generated by the thermoelectric element, and be coupled to and electrically conductive with the conducting wire member to transmit the received power to the sensor module.

Here, the sensor module may include: a sensor unit configured to detect information on a state of the one portion of the external member; a communication unit configured to be electrically conductive with the sensor unit and transfer the detected information to an external terminal: a sensor connector configured to be electrically conductive with the conducting wire member and receive the power; and a sensor PCB configured to be electrically conductive with each of the sensor unit, the communication unit, and the sensor connector to transmit the power to the sensor unit and the communication unit.

Also, the conducting wire member may include: a power connecting portion configured to be removably coupled to and electrically conductive with the power module: a sensor connecting portion configured to be removably coupled to and electrically conductive with the sensor module; and an extending portion extending between the power connecting portion and the sensor connecting portion and configured to be electrically conductive with each of the power connecting portion and the sensor connecting portion.

Here, the extending portion may be formed of a flexible material.

According to the above configuration, a wireless sensor device according to an embodiment of the present disclosure can reduce the size of space occupied thereby.

First, the wireless sensor device includes a power module and a sensor module. The power module and the sensor module are disposed apart from each other physically and electrically conductive with each other. That is, the power module and the sensor module are provided separately.

Therefore, compared to the case in which the power module and the sensor module are provided as a single member, the size and volume of each of the power module and the sensor module may be reduced. Accordingly, the size and volume of a space occupied by the wireless sensor device constituted by the power module and the sensor module may also be reduced.

Also, according to the above configuration, a wireless sensor device according to an embodiment of the present disclosure can improve a degree of freedom of arrangement of a component for information detection and a component that supplies power.

First, the wireless sensor device includes a conducting wire member coupled to each of a power module and a sensor module to make the power module and the sensor module electrically conductive with each other. The conducting wire member extends between the power module and the sensor module and is formed of a flexible material. That is, even when the power module and the sensor module connected to the conducting wire member are disposed at various positions, the conducting wire member may remain coupled to the power module and the sensor module.

The sensor module may be disposed at a position at which measurement of information is required, and the power module may be disposed at a different position. Even in this case, due to the conducting wire member, the sensor module may operate by receiving power from the power module.

Therefore, the degree of freedom of arrangement of the power module and the sensor module can be improved. Accordingly, the degree of freedom of arrangement of the wireless sensor device can also be improved.

Also, according to the above configuration, a wireless sensor device according to an embodiment of the present disclosure can prevent damage to a component that supplies power.

As described above, a power module and a sensor module may be disposed apart from each other. Therefore, the sensor module may be disposed adjacent to an information detection target, and the power module may be disposed at a position at which damage due to an external environment can be prevented.

For example, the sensor module may be disposed adjacent to a high-temperature member and configured to detect information on a temperature of the member. On the other hand, the power module may be spaced apart from the high-temperature member, disposed at a position with a relatively low temperature, and configured to supply power to the sensor module.

Therefore, the power module may be disposed apart from a position prone to damage due to the external environment and may supply power to the sensor module. Accordingly, since the possibility of damage to the power module is decreased, the service life of the wireless sensor device may be increased, and the time and cost required for maintenance and repair may be reduced.

Also, according to the above configuration, a wireless sensor device according to an embodiment of the present disclosure can supply power in various manners to correspond to various environments.

In one embodiment, a power module may be provided to include a coil member configured to produce power in a magnetic field energy harvesting manner. In the embodiment, the power module may be coupled to an alternating current carrying member to produce power and transmit the power to a sensor module. The power module according to the present embodiment may be applied when an information measurement target member carries alternating current.

In another embodiment, a power module may be provided to include a battery pack charged by an external power source and configured to store the power and transmit the stored power to a sensor module. In the embodiment, the power module may be disposed at an arbitrary position and transmit power to the sensor module. The power module according to the present embodiment may be applied in an environment in which it is difficult to apply a separate power source from the outside.

In still another embodiment, a power module may be provided to include a thermoelectric element configured to produce power using a temperature difference. In the embodiment, the power module may be coupled to a high-temperature member to produce power and transmit the power to a sensor module. The power module according to the present embodiment may be applied when an information measurement target member is at a high temperature.

Therefore, the power module may be provided in different forms according to a state of an information measurement target member or an environment in which the member is located. Accordingly, the power module may supply power to the sensor module while actively adjusting to various states of the member and various environments.

Also, according to the above configuration, a wireless sensor device according to an embodiment of the present disclosure can facilitate maintenance and repair.

As described above, components constituting the wireless sensor device, that is, a power module, a sensor module, and a conducting wire member, are separately provided and are removably coupled to and electrically conductive with each other.

Therefore, when any one of the components requires maintenance and repair or replacement, only the corresponding component may be separated for repair or replacement to perform maintenance and repair of the wireless sensor device. Accordingly, the time and cost required for the maintenance and repair of the wireless sensor device can be reduced.

It should be understood that the effects of the present disclosure are not limited to the above-described effects, and include all effects inferable from a configuration of the disclosure described in detailed descriptions or claims of the present disclosure.

### BRIEF DESCRIPTION OF THE DRAWINGS

FIG. 1 is a perspective view illustrating a wireless sensor device according to one embodiment of the present disclosure.

FIG. 2 is a perspective view illustrating the wireless sensor device of FIG. 1 at a different angle.

FIG. 3 is an exploded perspective view illustrating a coupling structure of the wireless sensor device of FIG. 1.

FIG. 4 is an exploded perspective view illustrating components of the wireless sensor device of FIG. 1.

FIG. 5 is a perspective view illustrating a wireless sensor device according to another embodiment of the present disclosure.

FIG. 6 is a perspective view illustrating the wireless sensor device of FIG. 5 at a different angle.

FIG. 7 is an exploded perspective view illustrating a coupling structure of the wireless sensor device of FIG. 5.

FIG. 8 is an exploded perspective view illustrating components of the wireless sensor device of FIG. 5.

FIG. 9 is a perspective view illustrating a wireless sensor device according to still another embodiment of the present disclosure.

FIG. 10 is a perspective view illustrating the wireless sensor device of FIG. 9 at a different angle.

FIG. 11 is an exploded perspective view illustrating a coupling structure of the wireless sensor device of FIG. 9.

FIG. 12 is an exploded perspective view illustrating components of the wireless sensor device of FIG. 9.

FIG. 13 is a perspective view illustrating wireless sensor devices according to various embodiments of the present disclosure.

FIG. 14 is a front view illustrating the wireless sensor devices according to various embodiments of the present disclosure.

### DETAILED DESCRIPTION

Hereinafter, embodiments of the present disclosure will be described in detail with reference to the accompanying drawings so that those skilled in the art to which the present disclosure pertains can easily carry out the embodiments. The present disclosure may be implemented in many different forms and is not limited to the embodiments described herein. In order to clearly describe the present disclosure, portions not related to the description are omitted from the accompanying drawings, and the same or similar components are denoted by the same reference numerals throughout the specification.

The words and terms used in the specification and the claims are not construed as being limited to their ordinary or dictionary meanings, and should be construed with meanings and concepts consistent with the technical spirit of the present disclosure in accordance with the principle that the inventors can define terms and concepts in order to best describe their disclosure.

Therefore, the embodiments described in the specification and configurations illustrated in the drawings correspond to exemplary embodiments of the present disclosure and do not entirely represent the technical spirit of the present disclosure, and thus various equivalents and modifications that may replace the corresponding configurations may be present at the time of filing this application.

In the following description, descriptions of some components may be omitted to clarify features of the present disclosure.

### 1. Definition of Terms

The term “electrically conductive” used in the following description means that two or more members are connected to be able to transmit an electrical signal or current to each other. In one embodiment, an electrically conductive state may be formed in a wired form using a conducting wire member or the like or a wireless form using radio frequency identification (RFID), Bluetooth, Wi-Fi, or the like.

The term “communicate” used in the following description means that two or more members are connected to be able to fluidly communicate with each other. In one embodiment, a communicating state may be formed by spaces formed in the two or more members. Alternatively, a communicating state may be formed by a member such as a pipe, a duct, or a hose.

The terms “upper side,” “lower side,” “front side,” “rear side,” “left side,” and “right side” used in the following description may be understood with reference to the coordinate system illustrated throughout the accompanying drawings.

The term “measurement target member” used in the following description refers to an object on which wireless sensor devices 10, 20, and 30 according to different embodiments are provided to obtain various pieces of information. In one embodiment, a measurement target member may be located in a harsh condition such as a high-temperature condition or a high-pressure condition.

Also, in the following description, a sensor unit 240 is illustrated as facing an upper side to clarify technical features of the wireless sensor devices 10, 20, and 30 according to different embodiments. Thus, it should be understood that the wireless sensor devices 10, 20, and 30 according to different embodiments may be disposed so that an upper portion thereof is located adjacent to a measurement target member.

In the following description, it is assumed that the wireless sensor devices 10, 20, and 30 according to different embodiments of the present disclosure are provided in a circuit breaker. However, it should be understood that the wireless sensor devices 10, 20, and 30 according to different embodiments which will be described below may be utilized by being provided in an arbitrary device for which measurement of various pieces of information such as temperature, pressure, and vibration is required.

### 2. Description of Wireless Sensor Device 10 According to One Embodiment of the Present Disclosure

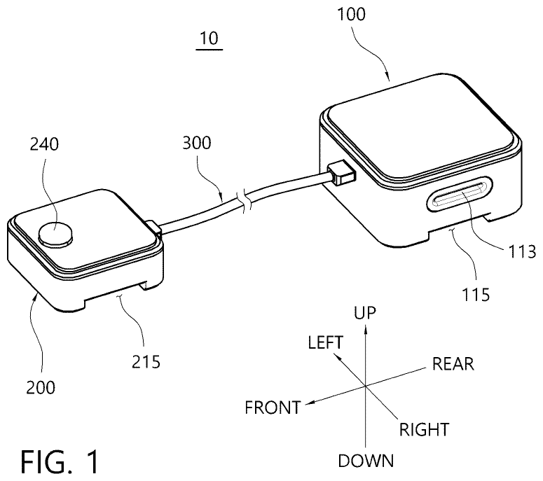

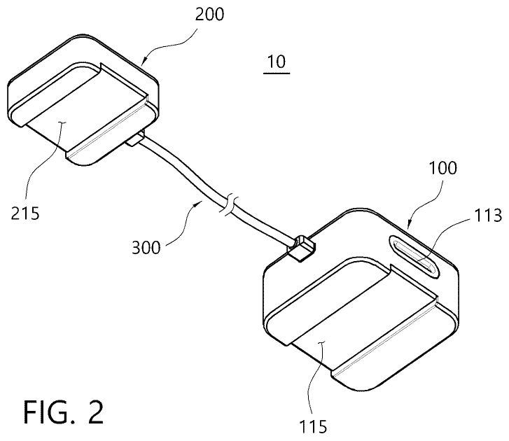

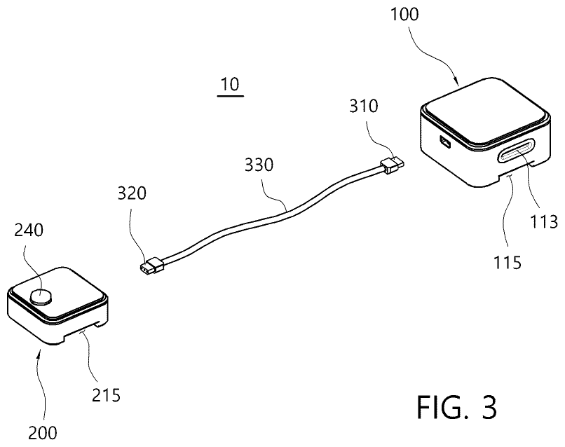

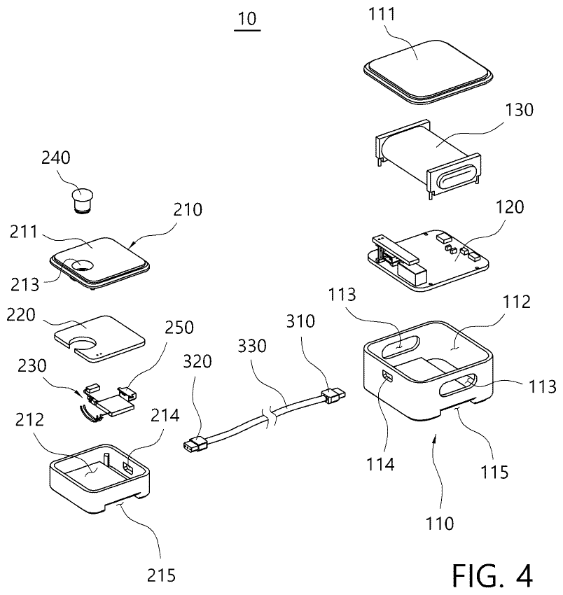

Referring to FIGS. 1 to 4, a wireless sensor device 10 according to one embodiment of the present disclosure is illustrated.

In the wireless sensor device 10 according to the present embodiment, a component for measuring various pieces of information such as temperature, pressure, and vibration and a component that sends detected information to an external terminal (not illustrated) are disposed adjacent to each other. Also, in the wireless sensor device 10 according to the present embodiment, a component for supplying power to the components is disposed apart from the components.

Accordingly, in the wireless sensor device 10 according to the present embodiment, the size and weight of each portion may be reduced.

Also, since the information detecting component and the power supplying component are spaced apart from each other, the information detecting component may be disposed at an information detection target position, and the power supplying component may be spaced apart therefrom and disposed at a relatively safe position.

Consequently, the wireless sensor device 10 according to the present embodiment may be disposed at an arbitrary position at which measurement of information is required and may be configured to stably detect information.

The wireless sensor device 10 may be formed to longitudinally extend in one direction, that is, the front-rear direction in the illustrated embodiment. As will be described below, each of the components of the wireless sensor device 10 may be electrically conductive due to a conducting wire member 300. It should be understood that the direction in which the wireless sensor device 10 longitudinally extends may be changed in an embodiment in which the conducting wire member 300 is formed of a flexible material.

In the illustrated embodiment, the wireless sensor device 10 includes a power module 100, a sensor module 200, and the conducting wire member 300.

The power module 100 supplies power to the sensor module 200. The power module 100 is electrically conductive with the sensor module 200.

The power module 100 may be provided in an arbitrary form that allows the power module 100 to supply power to the sensor module 200. In the wireless sensor device 10 according to the present embodiment, the power module 100 is provided in a form in which magnetic field energy harvesting is possible.

The power module 100 is disposed apart from the sensor module 200. In one embodiment, the power module 100 may be provided separately from and disposed apart from the sensor module 200.

The power module 100 is removably coupled to the conducting wire member 300. The power module 100 may be electrically conductive with the sensor module 200 due to the conducting wire member 300.

In the illustrated embodiment, the power module 100 is formed in the shape of a quadrangular column that has a quadrangular cross-section in the horizontal direction thereof and has a height in the up-down direction. The power module 100 may have an arbitrary shape that allows the power module 100 to be electrically conductive with the sensor module 200 and supply power thereto.

In the illustrated embodiment, the power module 100 includes a power housing 110, a power PCB 120, a coil member 130, and a power connector 140.

The power housing 110 forms a body of the power module 100. The power housing 110 is a portion of the power module 100 that is exposed to the outside. The power housing 110 may be formed in a shape that corresponds to the power module 100 described above, that is, the quadrangular column shape in the illustrated embodiment.

The power housing 110 is disposed apart from a sensor housing 210 of the sensor module 200. The power housing 110 may be disposed independently from the sensor housing 210.

In the illustrated embodiment, the power housing 110 includes a power cover 111, a power space 112, a band coupling portion 113, a connector coupling portion 114, and a tying space portion 115.

The power cover 111 forms one side surface of the power housing 110. In the illustrated embodiment, the power cover 111 forms an upper side surface of the power housing 110. As described above, the wireless sensor device 10 according to the present embodiment may be disposed so that an upper side thereof is adjacent to a measurement target member. Thus, the power cover 111 may be defined as one surface facing the measurement target member.

The power cover 111 may be removably coupled to another surface of the power housing 110. The power cover 111 may be coupled to another surface of the power housing 110 while covering the power space 112 from one side, that is, an upper side in the illustrated embodiment.

The power space 112 is a space formed in the power housing 110. Various components that constitute the power module 100 may be accommodated in the power space 112. In the illustrated embodiment, the power PCB 120, the coil member 130, and the power connector 140 are accommodated in the power space 112.

The power space 112 may be defined by being surrounded by each surface of the power housing 110. In the illustrated embodiment, the power space 112 is formed by being surrounded by a front side, a rear side, a left side, a right side, and a lower side surface of the power housing 110. Also, an upper side of the power space 112 may be covered by the power cover 111.

The power space 112 is electrically conductive with the outside. The power connector 140 accommodated in the power space 112 may be electrically conductive with the sensor module 200 due to the conducting wire member 300.

The power space 112 communicates with the outside. A ferromagnetic band member (not illustrated) that passes through the coil member 130 may pass through the power space 112.

The band coupling portion 113 forms a passage that allows the band member (not illustrated) to pass therethrough. The band member (not illustrated) may pass through the band coupling portion 113, extend to the power space 112, and then extend to the outside again. The band coupling portion 113 allows communication between the power space 112 and the outside.

The band coupling portion 113 is formed to pass through any one or more surfaces of the power housing 110. Also, a plurality of band coupling portions 113 may be formed, and a band member (not illustrated) that passes through any one band coupling portion 113 and extends to the power space 112 may extend to the outside of the power housing 110 through another band coupling portion 113.

In the illustrated embodiment, the band coupling portion 113 is formed in each of the left side surface and the right side surface of the power housing 110. In other words, the band coupling portion 113 is provided as a pair of band coupling portions 113 disposed to face each other with the power space 112 disposed therebetween.

The band coupling portion 113 may have an arbitrary shape that allows the band member (not illustrated) to pass therethrough. In the illustrated embodiment, the band coupling portion 113 is formed as a plate-shaped space that has a thickness in the left-right direction and an extension length in the front-rear direction longer than an extension length in the up-down direction.

The connector coupling portion 114 is a portion through which the power connector 140 is exposed to the outside. A power connecting portion 310 of the conducting wire member 300 may pass through the connector coupling portion 114 and be coupled to and electrically conductive with the power connector 140. The connector coupling portion 114 allows communication between the power space 112 and the outside.

The connector coupling portion 114 is formed to pass through another surface of the power housing 110. In the illustrated embodiment, the connector coupling portion 114 is formed in the front side surface of the power housing 110. In other words, the connector coupling portion 114 is formed to pass through one surface of the power housing 110 that faces the sensor module 200.

The connector coupling portion 114 may have an arbitrary shape that allows the power connecting portion 310 of the conducting wire member 300 to pass therethrough. That is, the connector coupling portion 114 may have a shape that corresponds to the shape of the power connecting portion 310. In the illustrated embodiment, the connector coupling portion 114 is formed as a plate-shaped space that has a thickness in the front-rear direction and an extension length in the left-right direction longer than an extension length in the up-down direction.

The tying space portion 115 is a space in which a tying member (not illustrated) for coupling the power housing 110 to a measurement target member is accommodated. In one embodiment, the tying member (not illustrated) may be provided in an arbitrary form that can couple two or more members, such as a string or a rubber band.

The tying space portion 115 is formed in still another surface of the power housing 110. In the illustrated embodiment, the tying space portion 115 is formed in the lower side surface of the power housing 110. In an embodiment in which the sensor unit 240 is disposed to lean toward an upper side, the tying space portion 115 is disposed opposite to a measurement target member.

Therefore, a worker may easily recognize the tying space portion 115 and use the tying member (not illustrated) to couple the power module 100 to the measurement target member.

The tying space portion 115 may be formed in an arbitrary form that can partially accommodate the tying member (not illustrated). In the illustrated embodiment, the tying space portion 115 has the shape of a groove that has a predetermined width in the front-rear direction, is formed to be penetrated in the left-right direction, and is formed to be recessed in the lower surface of the power housing 110.

The power PCB 120 electrically connects the coil member 130 and the power connector 140. Power generated by the coil member 130 may be transmitted to the sensor module 200 through the power connector 140.

The power PCB 120 is accommodated in the power space 112. When the power cover 111 is coupled to another surface of the power housing 110 while covering the power space 112, the power PCB 120 is not arbitrarily exposed to the outside.

The power PCB 120 is electrically conductive with the coil member 130 and the power connector 140. The power PCB 120 is coupled to each of the coil member 130 and the power connector 140. Since a process in which the coil member 130 and the power connector 140 become electrically conductive with each other due to the power PCB 120 is widely known art, detailed description thereof will be omitted.

The power PCB 120 may be provided in an arbitrary form that allows the coil member 130 and the power connector 140 to be electrically conductive with each other. In the illustrated embodiment, the power PCB 120 is provided in the shape of a quadrangular plate that has a quadrangular cross-section in the horizontal direction thereof and has a thickness in the up-down direction.

The coil member 130 is disposed adjacent to the power PCB 120, that is, at an upper side of the power PCB 120 in the illustrated embodiment.

The coil member 130 produces power in a magnetic field energy harvesting manner as described above. The produced power may be transmitted to the sensor module 200 and utilized for an operation of the sensor module 200.

The coil member 130 is coupled to and electrically conductive with the power PCB 120. The coil member 130 may be coupled to and electrically conductive with the power connector 140 due to the power PCB 120.

The band member (not illustrated) passes through the coil member 130. The coil member 130 may produce power as the size and direction of the magnetic field formed by the band member (not illustrated) change.

The coil member 130 may be provided in an arbitrary form that allows the band member (not illustrated) to pass therethrough and produces power. In the illustrated embodiment, the coil member 130 has the shape of a solid figure that has a height in the up-down direction and an extension length in the left-right direction longer than an extension length in the front-rear direction.

A hollow formed to extend in the longitudinal direction of the coil member 130, that is, the left-right direction in the illustrated embodiment, may be formed in the coil member 130. The band member (not illustrated) may pass through the hollow.

Since a process in which the coil member 130 produces power in the magnetic field energy harvesting manner is widely known art, detailed description thereof will be omitted.

The power connector 140 is located adjacent to the coil member 130.

The power connector 140 receives power produced by the coil member 130 and transmits the received power to the sensor module 200.

The power connector 140 is coupled to and electrically conductive with the power PCB 120. The power connector 140 may be coupled to and electrically conductive with the coil member 130 due to the power PCB 120.

The power connector 140 is removably coupled to and electrically conductive with the power connecting portion 310 of the conducting wire member 300. In one embodiment, a space may be formed in the power connector 140, and the power connecting portion 310 may be coupled to the power connector 140 by being inserted into the space.

The power connector 140 is coupled to and electrically conductive with the sensor module 200. The power connector 140 may be coupled to and electrically conductive with the sensor module 200 due to the conducting wire member 300.

The power connector 140 may be disposed at an arbitrary position at which the power connector 140 can be coupled to and electrically conductive with the conducting wire member 300. In the illustrated embodiment, the power connector 140 is located adjacent to the connector coupling portion 114 formed in one surface, that is, the front side surface, of the power housing 110 that faces the sensor module 200.

In the embodiment, the power connector 140 may be disposed to overlap the connector coupling portion 114. In the illustrated embodiment, the power connector 140 is disposed to overlap the connector coupling portion 114 in a direction in which the power module 100 and the sensor module 200 are spaced apart, that is, the front-rear direction.

The sensor module 200 is located adjacent to a measurement target member and detects arbitrary information related to a state of the measurement target member. The information detected by the sensor module 200 may be transferred to an external terminal (not illustrated) and utilized to identify the state of the measurement target member.

The sensor module 200 does not have a separate power source. That is, the sensor module 200 may be electrically conductive with the power module 100 and receive power necessary for operation from the power module 100. The sensor module 200 is removably coupled to and electrically conductive with the power module 100 due to the conducting wire member 300.

The sensor module 200 is disposed apart from the power module 100. That is, when the wireless sensor device 10 according to the present embodiment is installed, the sensor module 200 and the power module 100 may be disposed at different positions. Here, since the sensor module 200 and the power module 100 are coupled to and electrically conductive with each other due to the conducting wire member 300 which will be described below, it should be understood that the sensor module 200 and the power module 100 may be disposed adjacent to each other when necessary.

The sensor module 200 is electrically conductive with an external terminal (not illustrated). Information detected by the sensor module 200 may be transferred to the external terminal (not illustrated). In one embodiment, the sensor module 200 may be electrically conductive with the external terminal (not illustrated) in a wireless manner.

In the illustrated embodiment, the sensor module 200 has the shape of a quadrangular column that has a quadrangular cross-section in the horizontal direction thereof and has a height in the up-down direction. The sensor module 200 may have an arbitrary shape that allows the sensor module 200 to be electrically conductive with the power module 100, operate with power transmitted from the power module 100, and collect various pieces of information.

In the illustrated embodiment, the sensor module 200 includes the sensor housing 210, a sensor PCB 220, a communication unit 230, the sensor unit 240, and a sensor connector 250.

The sensor housing 210 forms a body of the sensor module 200. The sensor housing 210 is a portion of the sensor module 200 that is exposed to the outside. The sensor housing 210 may be formed in a shape that corresponds to the sensor module 200 described above, that is, the quadrangular column shape in the illustrated embodiment.

The sensor housing 210 is disposed apart from the power housing 110 of the power module 100. The sensor housing 210 may be disposed independently from the power housing 110.

In the illustrated embodiment, the sensor housing 210 includes a sensor cover 211, a sensor space 212, a unit through-portion 213, a connector coupling portion 214, and a tying space portion 215.

The sensor cover 211 forms one side surface of the sensor housing 210. In the illustrated embodiment, the sensor cover 211 forms an upper side surface of the sensor housing 210.

As described above, the wireless sensor device 10 according to the present embodiment may be disposed so that the upper side thereof is adjacent to a measurement target member. Thus, the sensor cover 211 may be defined as one surface facing the measurement target member.

The sensor cover 211 may be removably coupled to another surface of the sensor housing 210. The sensor cover 211 may be coupled to another surface of the sensor housing 210 while covering the sensor space 212 from one side, that is, an upper side in the illustrated embodiment.

The sensor space 212 is a space formed in the sensor housing 210. Various components that constitute the sensor module 200 may be accommodated in the sensor space 212.

In the illustrated embodiment, the sensor PCB 220, the communication unit 230, and the sensor connector 250 are accommodated in the sensor space 212. Also, a portion of the sensor unit 240 is accommodated in the sensor space 212.

The sensor space 212 may be defined by being surrounded by each surface of the sensor housing 210. In the illustrated embodiment, the sensor space 212 is formed by being surrounded by a front side, a rear side, a left side, a right side, and a lower side surface of the sensor housing 210. Also, an upper side of the sensor space 212 may be covered by the sensor cover 211.

The sensor space 212 is electrically conductive with the outside. The sensor connector 250 accommodated in the sensor space 212 may be electrically conductive with the power module 100 due to the conducting wire member 300.

The unit through-portion 213 forms a passage through which the sensor unit 240 is exposed to the outside. As will be described below, one end of the sensor unit 240 in an extending direction thereof, that is, a lower side end of the sensor unit 240 in the illustrated embodiment, is accommodated in the sensor space 212, and the other end of the sensor unit 240 in the extending direction thereof, that is, an upper side end of the sensor unit 240 in the illustrated embodiment, is exposed to the outside of the sensor housing 210.

The unit through-portion 213 is formed to pass through one surface of the sensor housing 210 covering the sensor space 212, that is, the sensor cover 211 in the illustrated embodiment, and serves as a passage allowing the sensor unit 240 to extend inside and outside the sensor housing 210.

The unit through-portion 213 may have an arbitrary shape that allows the sensor unit 240 to pass therethrough. In the illustrated embodiment, the unit through-portion 213 has a disk shape that has a circular cross-section and has a thickness in the up-down direction. The shape of the unit through-portion 213 may be changed according to the shape of the sensor unit 240.

The connector coupling portion 214 is a portion through which the sensor connector 250 is exposed to the outside. A sensor connecting portion 320 of the conducting wire member 300 may pass through the connector coupling portion 214 and be coupled to and electrically conductive with the sensor connector 250. The connector coupling portion 214 allows communication between the sensor space 212 and the outside.

The connector coupling portion 214 is formed to pass through another surface of the sensor housing 210. In the illustrated embodiment, the connector coupling portion 214 is formed in the rear side surface of the sensor housing 210. In other words, the connector coupling portion 214 is formed to pass through one surface of the sensor housing 210 that faces the power module 100.

The connector coupling portion 214 may have an arbitrary shape that allows the sensor connecting portion 320 of the conducting wire member 300 to pass therethrough. That is, the connector coupling portion 214 may have a shape that corresponds to the shape of the sensor connecting portion 320. In the illustrated embodiment, the connector coupling portion 214 is formed as a plate-shaped space that has a thickness in the front-rear direction and an extension length in the left-right direction longer than an extension length in the up-down direction.

The tying space portion 215 is a space in which a tying member (not illustrated) for coupling the sensor housing 210 to a measurement target member is accommodated. In one embodiment, as described above, the tying member (not illustrated) may be provided in an arbitrary form that can couple two or more members, such as a string or a rubber band.

The tying space portion 215 is formed in still another surface of the sensor housing 210. In the illustrated embodiment, the tying space portion 215 is formed in the lower side surface of the sensor housing 210. In an embodiment in which the sensor unit 240 is disposed to lean toward an upper side, the tying space portion 215 is disposed opposite to a measurement target member.

Therefore, a worker may easily recognize the tying space portion 215 and use the tying member (not illustrated) to couple the sensor module 200 to the measurement target member.

The tying space portion 215 may be formed in an arbitrary form that can partially accommodate the tying member (not illustrated). In the illustrated embodiment, the tying space portion 215 has the shape of a groove that has a predetermined width in the front-rear direction, is formed to be penetrated in the left-right direction, and is formed to be recessed in the lower surface of the sensor housing 210.

The sensor PCB 220 electrically connects the communication unit 230, the sensor unit 240, and the sensor connector 250. Power transmitted through the sensor connector 250 may be transmitted to the communication unit 230 and the sensor unit 240. Also, information detected by the sensor unit 240 may be transferred to the communication unit 230 and sent to an external terminal (not illustrated).

The sensor PCB 220 is accommodated in the sensor space 212. When the sensor cover 211 is coupled to another surface of the sensor housing 210 while covering the sensor space 212, the sensor PCB 220 is not arbitrarily exposed to the outside.

The sensor PCB 220 is electrically conductive with each of the communication unit 230, the sensor unit 240, and the sensor connector 250. The sensor PCB 220 is coupled to each of the communication unit 230, the sensor unit 240, and the sensor connector 250. Since a process in which the communication unit 230, the sensor unit 240, and the sensor connector 250 become electrically conductive with each other due to the sensor PCB 220 is widely known art, detailed description thereof will be omitted.

The sensor PCB 220 may be provided in an arbitrary form that allows the communication unit 230, the sensor unit 240, and the sensor connector 250 to be electrically conductive with each other. In the illustrated embodiment, the sensor PCB 220 is provided in the shape of a quadrangular plate that has a quadrangular cross-section in the horizontal direction thereof and has a thickness in the up-down direction.

Although not denoted by a reference numeral, a hole through which the sensor unit 240 passes may be formed in the sensor PCB 220. The hole may be disposed to overlap the unit through-portion 213 in a direction in which the sensor unit 240 extends, that is, the up-down direction in the illustrated embodiment.

The communication unit 230 is disposed adjacent to the sensor PCB 220, that is, at a lower side of the sensor PCB 220 in the illustrated embodiment.

The communication unit 230 is electrically conductive with the sensor unit 240 and receives information detected by the sensor unit 240. The communication unit 230 may transfer the received information to an external terminal (not illustrated).

The communication unit 230 may be electrically conductive with the external terminal (not illustrated) in a wired or wireless manner. In the illustrated embodiment, the communication unit 230 is configured to communicate with the external terminal (not illustrated) in a wireless manner. In the embodiment, since a wired member is not required for an electrically conductive state between the communication unit 230 and the external terminal (not illustrated), installation, maintenance, and repair are facilitated.

The communication unit 230 may be provided in an arbitrary form that allows the communication unit 230 to be electrically conductive with the external terminal (not illustrated). In one embodiment, the communication unit 230 may be electrically conductive with the external terminal (not illustrated) using Wi-Fi, Bluetooth, RFID, and the like.

The communication unit 230 is coupled to and electrically conductive with the sensor PCB 220. The communication unit 230 may operate by receiving power transmitted to the sensor connector 250 through the sensor PCB 220. Also, the communication unit 230 may receive information detected by the sensor unit 240 through the sensor PCB 220.

In other words, the communication unit 230 is coupled to and electrically conductive with each of the sensor unit 240 and the sensor connector 250 through the sensor PCB 220.

The sensor unit 240 is disposed adjacent to the communication unit 230. The communication unit 230 and the sensor unit 240 may be electrically conductive with each other directly or through the sensor PCB 220.

The sensor unit 240 is located adjacent to a measurement target member and detects arbitrary information related to a state of the measurement target member. The information detected by the sensor module 200 may be transferred to an external terminal (not illustrated) and utilized to identify the state of the measurement target member.

The sensor unit 240 may be provided in an arbitrary form that allows the sensor unit 240 to detect arbitrary information related to the measurement target member. In one embodiment, the sensor unit 240 may be configured to detect any one or more pieces of information among the temperature, pressure, humidity level, gas composition, and vibration of the measurement target member.

In the embodiment, one or more sensor units 240 may be provided, and each sensor unit 240 may be configured to detect one or more pieces of information. In the illustrated embodiment, a single sensor unit 240 is provided and configured to detect temperature-related information.

The sensor unit 240 is coupled to and electrically conductive with the sensor PCB 220. Power necessary for operation of the sensor unit 240 may be transmitted to the sensor connector 250 through the sensor PCB 220. Also, information detected by the sensor unit 240 may be transferred to the communication unit 230 through the sensor PCB 220.

In other words, the sensor unit 240 is coupled to and electrically conductive with each of the communication unit 230 and the sensor connector 250 through the sensor PCB 220.

The sensor connector 250 is located adjacent to each of the sensor PCB 220, the communication unit 230, and the sensor unit 240.

The sensor connector 250 receives power produced by the coil member 130 of the power module 100 and transmits the received power to other components of the sensor module 200.

The sensor connector 250 is coupled to and electrically conductive with the sensor PCB 220. The power received by the sensor connector 250 may be transmitted to the communication unit 230 or the sensor unit 240 through the sensor PCB 220.

The sensor connector 250 is removably coupled to and electrically conductive with the sensor connecting portion 320 of the conducting wire member 300. In one embodiment, a space may be formed in the sensor connector 250, and the sensor connecting portion 320 may be coupled to the sensor connector 250 by being inserted into the space.

The sensor connector 250 is coupled to and electrically conductive with the power module 100. The sensor connector 250 may be coupled to and electrically conductive with the power module 100 due to the conducting wire member 300.

The sensor connector 250 may be disposed at an arbitrary position at which the sensor connector 250 can be coupled to and electrically conductive with the conducting wire member 300. In the illustrated embodiment, the sensor connector 250 is located adjacent to the connector coupling portion 214 formed in one surface, that is, the rear side surface, of the sensor housing 210 that faces the power module 100.

In the embodiment, the sensor connector 250 may be disposed to overlap the connector coupling portion 214. In the illustrated embodiment, the sensor connector 250 is disposed to overlap the connector coupling portion 214 in the direction in which the power module 100 and the sensor module 200 are spaced apart, that is, the front-rear direction.

The conducting wire member 300 allows the power module 100 and the sensor module 200 to be coupled to and electrically conductive with each other. Due to the conducting wire member 300, the power module 100 and the sensor module 200 may be electrically conductive with each other while disposed apart from each other physically.

The conducting wire member 300 extends between the power module 100 and the sensor module 200. In the illustrated embodiment, the conducting wire member 300 is formed to extend in the front-rear direction between the power module 100 located at the rear side and the sensor module 200 located at the front side.

The conducting wire member 300 is coupled to and electrically conductive with the power module 100. Specifically, the power connecting portion 310 located at one end of the conducting wire member 300 in an extending direction thereof is coupled to and electrically conductive with the power connector 140.

The conducting wire member 300 is coupled to and electrically conductive with the sensor module 200. Specifically, the sensor connecting portion 320 located at the other end of the conducting wire member 300 in the extending direction thereof is coupled to and electrically conductive with the sensor connector 250.

The conducting wire member 300 may be provided in an arbitrary form that allows the conducting wire member 300 to be coupled to each of two or more different members and allow the two or more members to be electrically conductive with each other. In one embodiment, the conducting wire member 300 may be provided in the form of a wire.

The conducting wire member 300 may be provided to be replaceable. That is, as described above, the conducting wire member 300 is removably coupled to each of the power module 100 and the sensor module 200 and allows the power module 100 and the sensor module 200 to be electrically conductive with each other.

When a separation distance between the power module 100 and the sensor module 200 decreases, the conducting wire member 300 may be replaced with another conducting wire member 300 having a shorter length. Conversely, when the separation distance between the power module 100 and the sensor module 200 increases, the conducting wire member 300 may be replaced with another conducting wire member 300 having a longer length.

Therefore, a degree of freedom of arrangement of the power module 100 and the sensor module 200 may be improved.

In the illustrated embodiment, the conducting wire member 300 includes the power connecting portion 310, the sensor connecting portion 320, and an extending portion 330.

The power connecting portion 310 forms, among ends of the conducting wire member 300 in an extending direction thereof, one end of the conducting wire member 300 that faces the power module 100, that is, a rear side end of the conducting wire member 300 in the illustrated embodiment. The power connecting portion 310 is coupled to the extending portion 330 and electrically conductive with the sensor connecting portion 320.

The power connecting portion 310 is removably coupled to and electrically conductive with the power module 100. Specifically, the power connecting portion 310 may be coupled to and electrically conductive with the power connector 140 and receive power produced by the coil member 130. In one embodiment, as described above, the power connecting portion 310 may be electrically conductive with the power connector 140 by being inserted into and coupled to the power connector 140.

The sensor connecting portion 320 forms, among the ends of the conducting wire member 300 in the extending direction thereof, the other end of the conducting wire member 300 that faces the sensor module 200, that is, a front side end of the conducting wire member 300 in the illustrated embodiment. The sensor connecting portion 320 is also coupled to the extending portion 330 and electrically conductive with the power connecting portion 310.

The sensor connecting portion 320 is removably coupled to and electrically conductive with the sensor module 200. Specifically, the sensor connecting portion 320 may be coupled to and electrically conductive with the sensor connector 250 and transmit power received from the power module 100 to the sensor module 200. In one embodiment, as described above, the sensor connecting portion 320 may be electrically conductive with the sensor connector 250 by being inserted into and coupled to the sensor connector 250.

In one embodiment, the power connecting portion 310 and the sensor connecting portion 320 may be coupled to the power connector 140 and the sensor connector 250, respectively, in a snap fit manner. In the embodiment, unless an external force of a predetermined magnitude or more is applied in a predetermined direction, the power connecting portion 310 and the sensor connecting portion 320 are not arbitrarily separated from the power connector 140 and the sensor connector 250.

The extending portion 330 is a portion of the conducting wire member 300 that extends between the power module 100 and the sensor module 200. The extending portion 330 substantially performs a role of transmitting power transmitted to the power connecting portion 310 to the sensor connecting portion 320.

The extending portion 330 extends between the power connecting portion 310 and the sensor connecting portion 320. Since the power connecting portion 310 and the sensor connecting portion 320 are defined as the ends of the conducting wire member 300 in the extending direction thereof as described above, the connecting portions 310 and 320 may also be defined as ends of the extending portion 330.

The extending portion 330 extends between the power module 100 and the sensor module 200. In the illustrated embodiment, the extending portion 330 extends in the front-rear direction.

The extending portion 330 may be formed of a flexible material. In the embodiment, the degree of freedom of arrangement of the power module 100 and the sensor module 200 may be improved without being limited due to the positions of the power module 100 and the sensor module 200 relative to each other.

The wireless sensor device 10 according to the present embodiment described above includes the power module 100 and the sensor module 200 formed and disposed apart from each other physically. The power module 100 and the sensor module 200 may be electrically conductive with each other due to the conducting wire member 300, and power produced in the power module 100 may be transmitted to the sensor module 200.

Therefore, as compared to the case in which a component for power production and a component for detection are both provided in a single member, the size and weight of each of the modules 100 and 200 can be reduced.

Also, various arrangement methods may be implemented. For example, the power module 100 that is easily damaged due to an external condition such as temperature may be placed in a safe environment, and only the sensor module 200 may be placed adjacent to a measurement target member.

Further, since the power module 100 and the sensor module 200 may be provided separately, when any one of the modules 100 and 200 is damaged, the wireless sensor device 10 may be continuously used after replacing only the corresponding module.

As a result, the durability and service life of the wireless sensor device 10 may be increased, and reliability of detected information may be improved. Further, since the degree of freedom of arrangement of the wireless sensor device 10 is improved due to the size reduction and modularization thereof, damage due to an external environment may also be prevented.

### 3. Description of Wireless Sensor Device 20 According to Another Embodiment of the Present Disclosure

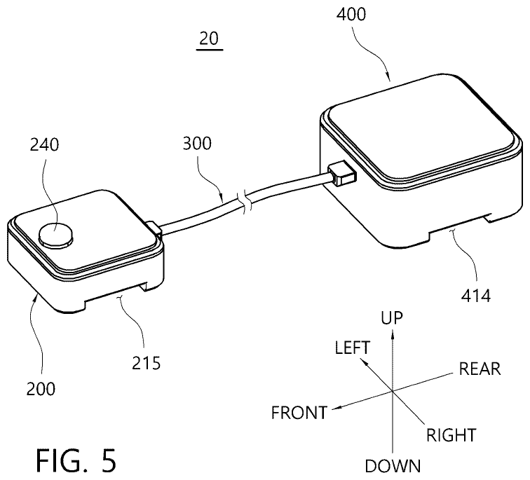

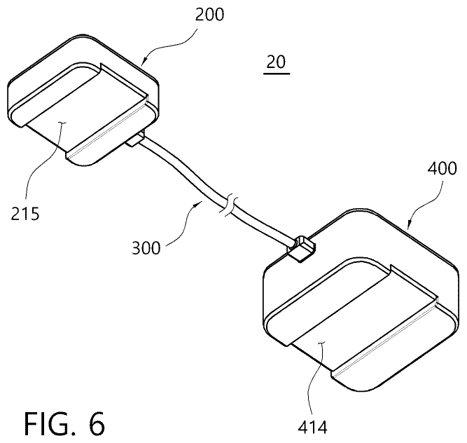

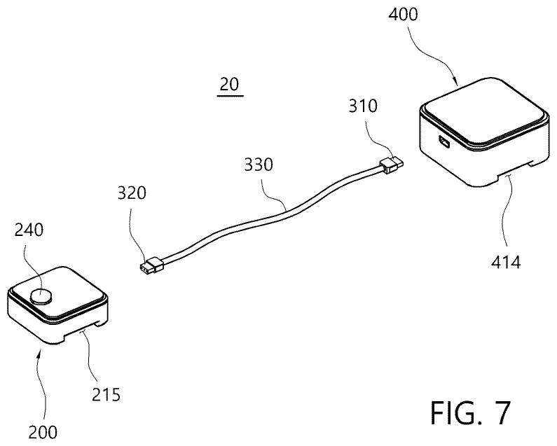

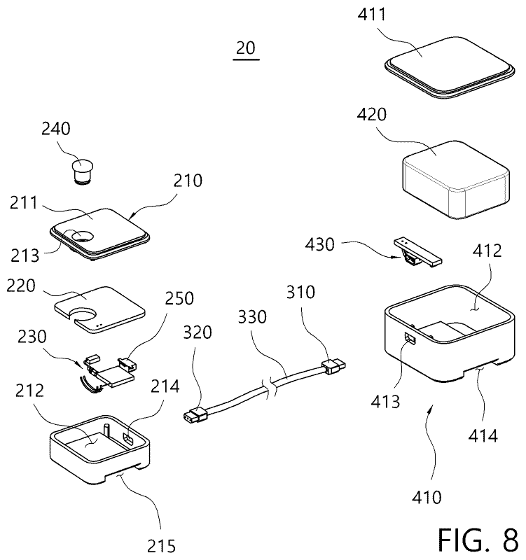

Referring to FIGS. 5 to 8, a wireless sensor device 20 according to another embodiment of the present disclosure is illustrated.

In the wireless sensor device 20 according to the present embodiment, a component for measuring various pieces of information such as temperature, pressure, and vibration and a component that sends detected information to an external terminal (not illustrated) are disposed adjacent to each other. Also, in the wireless sensor device 20 according to the present embodiment, a component for supplying power to the components is disposed apart from the components.

Accordingly, in the wireless sensor device 20 according to the present embodiment, the size and weight of each portion may be reduced.

Also, since the information detecting component and the power supplying component are spaced apart from each other, the information detecting component may be disposed at an information detection target position, and the power supplying component may be spaced apart therefrom and disposed at a relatively safe position.

Consequently, the wireless sensor device 20 according to the present embodiment may also be disposed at an arbitrary position at which measurement of information is required and may be configured to stably detect information.

The wireless sensor device 20 may be formed to longitudinally extend in one direction, that is, the front-rear direction in the illustrated embodiment. As will be described below, each of the components of the wireless sensor device 20 may be electrically conductive due to a conducting wire member 300. It should be understood that the direction in which the wireless sensor device 20 longitudinally extends may be changed in an embodiment in which the conducting wire member 300 is formed of a flexible material.

In the illustrated embodiment, the wireless sensor device 20 includes a sensor module 200, the conducting wire member 300, and a power module 400.

The sensor module 200 and the conducting wire member 300 provided in the wireless sensor device 20 according to the present embodiment have the same structures and functions as the sensor module 200 and the conducting wire member 300 provided in the wireless sensor device 10 according to the above-described embodiment. Thus, descriptions relating to the above-described embodiment may be referenced for descriptions of the sensor module 200 and the conducting wire member 300 according to the present embodiment, and the power module 400 will be mainly described in the following description.

The power module 400 supplies power to the sensor module 200. The power module 400 is electrically conductive with the sensor module 200.

The power module 400 may be provided in an arbitrary form that allows the power module 400 to supply power to the sensor module 200. In the wireless sensor device 20 according to the present embodiment, the power module 400 includes a battery and is provided in a rechargeable form.

The power module 400 is disposed apart from the sensor module 200. In one embodiment, the power module 400 may be provided separately from and disposed apart from the sensor module 200.

The power module 400 is coupled to the conducting wire member 300. The power module 400 may be electrically conductive with the sensor module 200 due to the conducting wire member 300.

In the illustrated embodiment, the power module 400 has the shape of a quadrangular column that has a quadrangular cross-section in the horizontal direction thereof and has a height in the up-down direction. The power module 400 may have an arbitrary shape that allows the power module 400 to be electrically conductive with the sensor module 200 and supply power thereto.

In the illustrated embodiment, the power module 400 includes a power housing 410, a battery pack 420, and a power connector 430.

The power housing 410 forms a body of the power module 400. The power housing 410 is a portion of the power module 400 that is exposed to the outside. The power housing 410 may be formed in a shape that corresponds to the power module 400 described above, that is, the quadrangular column shape in the illustrated embodiment.

The power housing 410 is disposed apart from a sensor housing 210 of the sensor module 200. The power housing 410 may be disposed independently from the sensor housing 210.

In the illustrated embodiment, the power housing 410 includes a power cover 411, a power space 412, a connector coupling portion 413, and a tying space portion 414.

The power cover 411 forms one side surface of the power housing 410. In the illustrated embodiment, the power cover 411 forms an upper side surface of the power housing 410. As described above, the wireless sensor device 20 according to the present embodiment may be disposed so that an upper side thereof is adjacent to a measurement target member. Thus, the power cover 411 may be defined as one surface facing the measurement target member.

The power cover 411 may be removably coupled to another surface of the power housing 410. The power cover 411 may be coupled to another surface of the power housing 410 while covering the power space 412 from one side, that is, an upper side in the illustrated embodiment.

The power space 412 is a space formed in the power housing 410. Various components that constitute the power module 400 may be accommodated in the power space 412. In the illustrated embodiment, the battery pack 420 and the power connector 430 are accommodated in the power space 412.

The power space 412 may be defined by being surrounded by each surface of the power housing 410. In the illustrated embodiment, the power space 412 is formed by being surrounded by a front side, a rear side, a left side, a right side, and a lower side surface of the power housing 410. Also, an upper side of the power space 412 may be covered by the power cover 411.

The power space 412 is electrically conductive with the outside. The power connector 430 accommodated in the power space 412 may be electrically conductive with the sensor module 200 due to the conducting wire member 300.

The connector coupling portion 413 is a portion through which the power connector 430 is exposed to the outside. A power connecting portion 310 of the conducting wire member 300 may pass through the connector coupling portion 413 and be coupled to and electrically conductive with the power connector 430. The connector coupling portion 413 allows communication between the power space 412 and the outside.

The connector coupling portion 413 is formed to pass through another surface of the power housing 410. In the illustrated embodiment, the connector coupling portion 413 is formed in the front side surface of the power housing 410. In other words, the connector coupling portion 413 is formed to pass through one surface of the power housing 410 that faces the sensor module 200.

The connector coupling portion 413 may have an arbitrary shape that allows the power connecting portion 310 of the conducting wire member 300 to pass therethrough. That is, the connector coupling portion 413 may have a shape that corresponds to the shape of the power connecting portion 310. In the illustrated embodiment, the connector coupling portion 413 is formed as a plate-shaped space that has a thickness in the front-rear direction and an extension length in the left-right direction longer than an extension length in the up-down direction.

The tying space portion 414 is a space in which a tying member (not illustrated) for coupling the power housing 410 to a measurement target member is accommodated. In one embodiment, as described above, the tying member (not illustrated) may be provided in an arbitrary form that can couple two or more members, such as a string or a rubber band.

The tying space portion 414 is formed in still another surface of the power housing 410. In the illustrated embodiment, the tying space portion 414 is formed in the lower side surface of the power housing 410. In an embodiment in which a sensor unit 240 is disposed to lean toward an upper side, the tying space portion 414 is disposed opposite to a measurement target member.

Therefore, a worker may easily recognize the tying space portion 414 and use the tying member (not illustrated) to couple the power module 400 to the measurement target member.

The tying space portion 414 may be formed in an arbitrary form that can partially accommodate the tying member (not illustrated). In the illustrated embodiment, the tying space portion 414 has the shape of a groove that has a predetermined width in the front-rear direction, is formed to be penetrated in the left-right direction, and is formed to be recessed in the lower surface of the power housing 410.

The battery pack 420 is charged by an external power source (not illustrated), stores power, and transmits the stored power to the sensor module 200. The battery pack 420 is electrically conductive with the sensor module 200.

The battery pack 420 is accommodated in the power space 412 of the power housing 410. The accommodated battery pack 420 is located adjacent to the power connector 430. The battery pack 420 is coupled to and electrically conductive with the power connector 430. The battery pack 420 may be electrically conductive with the conducting wire member 300 due to the power connector 430.

The battery pack 420 may be provided in an arbitrary form that allows the battery pack 420 to be charged by an external power source (not illustrated), store power, and transmit the stored power to another member. In one embodiment, the battery pack 420 may be provided in the form of a lithium ion (Li-Ion) battery or a lithium polymer (Li-Po) battery.

The battery pack 420 may be integrally provided with the power housing 410 or provided to be removable therefrom.

In an embodiment in which the battery pack 420 is integrally provided with the power housing 410, the battery pack 420 may receive power from an external power source (not illustrated) through the power connector 430. In an embodiment in which the battery pack 420 is provided separately from the power housing 410, the battery pack 420 may be coupled to a separately provided charging device (not illustrated) and receive power therefrom.

The battery pack 420 is located adjacent to the power connector 430 and is coupled to and electrically conductive with the power connector 430. In the illustrated embodiment, the power connector 430 is located at a lower side of the battery pack 420.

The power connector 430 receives power stored in the battery pack 420 and transmits the received power to the sensor module 200.

The power connector 430 is coupled to and electrically conductive with the battery pack 420. Also, the power connector 430 is coupled to and electrically conductive with the power connecting portion 310 of the conducting wire member 300. In one embodiment, a space may be formed in the power connector 430, and the power connecting portion 310 may be coupled to the power connector 430 by being inserted into the space.

Accordingly, the power stored in the battery pack 420 may be transmitted to the conducting wire member 300 via the power connector 430.

The power connector 430 is removably coupled to and electrically conductive with the sensor module 200. The power connector 430 may be coupled to and electrically conductive with the sensor module 200 due to the conducting wire member 300.

The power connector 430 may be disposed at an arbitrary position at which the power connector 430 can be coupled to and electrically conductive with the conducting wire member 300. In the illustrated embodiment, the power connector 430 is located adjacent to the connector coupling portion 413 formed in one surface, that is, the front side surface, of the power housing 410 that faces the sensor module 200.

In the embodiment, the power connector 430 may be disposed to overlap the connector coupling portion 413. In the illustrated embodiment, the power connector 430 is disposed to overlap the connector coupling portion 413 in a direction in which the power module 400 and the sensor module 200 are spaced apart, that is, the front-rear direction.

The wireless sensor device 20 according to the present embodiment described above also includes the power module 400 and the sensor module 200 formed and disposed apart from each other physically. The power module 400 and the sensor module 200 may be electrically conductive with each other due to the conducting wire member 300, and power produced in the power module 400 may be transmitted to the sensor module 200.

Therefore, as compared to the case in which a component for power production and a component for detection are both provided in a single member, the size and weight of each of the modules 200 and 400 can be reduced.

Also, various arrangement methods may be implemented. For example, the power module 400 that is easily damaged due to an external condition such as temperature may be placed in a safe environment, and only the sensor module 200 may be placed adjacent to a measurement target member.

Further, since the power module 400 and the sensor module 200 may be provided separately, when any one of the modules 200 and 400 is damaged, the wireless sensor device 20 may be continuously used after replacing only the corresponding module.

As a result, the durability and service life of the wireless sensor device 20 may be increased, and reliability of detected information may be improved. Further, since the degree of freedom of arrangement of the wireless sensor device 20 is improved due to the size reduction and modularization thereof, damage due to an external environment may also be prevented.

### 4. Description of Wireless Sensor Device 30 According to Still Another Embodiment of the Present Disclosure

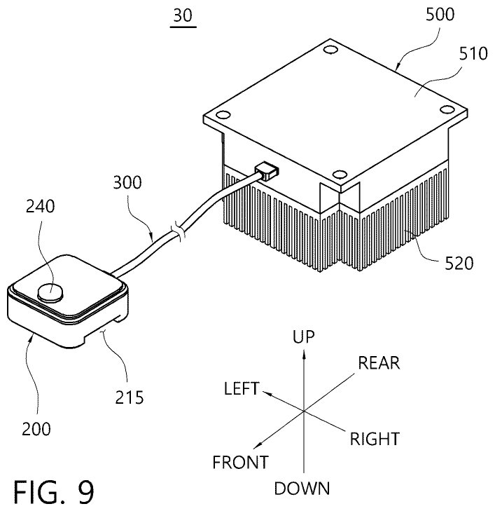

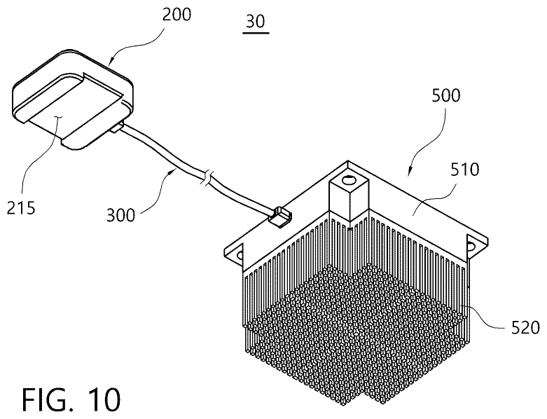

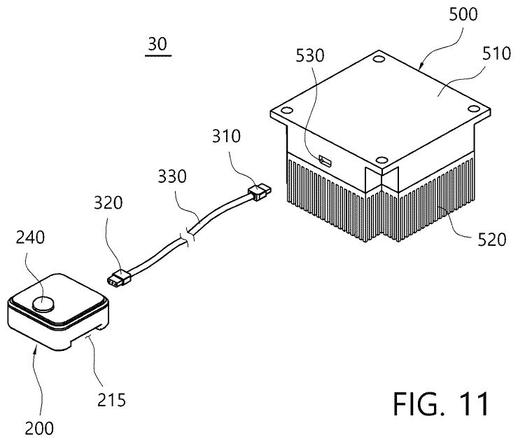

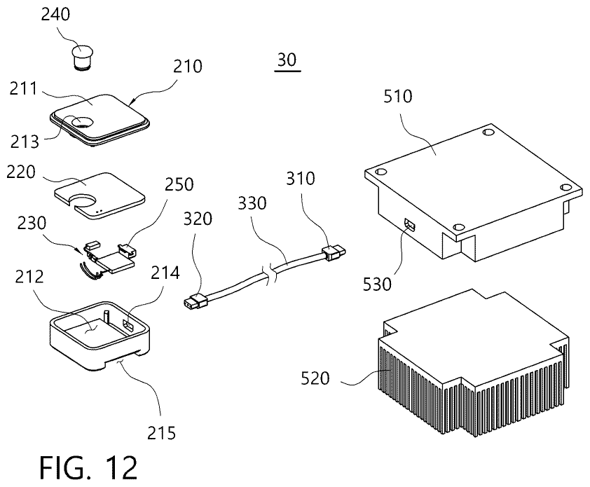

Referring to FIGS. 9 to 12, a wireless sensor device 30 according to still another embodiment of the present disclosure is illustrated.

In the wireless sensor device 30 according to the present embodiment, a component for measuring various pieces of information such as temperature, pressure, and vibration and a component that sends detected information to an external terminal (not illustrated) are disposed adjacent to each other. Also, in the wireless sensor device 30 according to the present embodiment, a component for supplying power to the components is disposed apart from the components.

Accordingly, in the wireless sensor device 30 according to the present embodiment, the size and weight of each portion may be reduced.

Also, since the information detecting component and the power supplying component are spaced apart from each other, the information detecting component may be disposed at an information detection target position, and the power supplying component may be spaced apart therefrom and disposed at a relatively safe position.

Consequently, the wireless sensor device 30 according to the present embodiment may also be disposed at an arbitrary position at which measurement of information is required and may be configured to stably detect information.

The wireless sensor device 30 may be formed to longitudinally extend in one direction, that is, the front-rear direction in the illustrated embodiment. As will be described below, each of the components of the wireless sensor device 30 may be electrically conductive due to a conducting wire member 300. It should be understood that the direction in which the wireless sensor device 30 longitudinally extends may be changed in an embodiment in which the conducting wire member 300 is formed of a flexible material.

In the illustrated embodiment, the wireless sensor device 30 includes a sensor module 200, the conducting wire member 300, and a power module 500.

The sensor module 200 and the conducting wire member 300 provided in the wireless sensor device 30 according to the present embodiment have the same structures and functions as the sensor module 200 and the conducting wire member 300 provided in each of the wireless sensor devices 10 and 20 according to the above-described embodiments. Thus, descriptions relating to the above-described embodiments may be referenced for descriptions of the sensor module 200 and the conducting wire member 300 according to the present embodiment, and the power module 500 will be mainly described in the following description.

The power module 500 supplies power to the sensor module 200. The power module 500 is electrically conductive with the sensor module 200.

The power module 500 may be provided in an arbitrary form that allows the power module 500 to supply power to the sensor module 200. In the wireless sensor device 30 according to the present embodiment, the power module 500 includes an element using the Peltier effect and is configured to generate power using a temperature difference.

The power module 500 is disposed apart from the sensor module 200. In one embodiment, the power module 500 may be provided separately from and disposed apart from the sensor module 200.

The power module 500 is coupled to the conducting wire member 300. The power module 500 may be electrically conductive with the sensor module 200 due to the conducting wire member 300.

In the illustrated embodiment, the power module 500 has the shape of a quadrangular column that has a quadrangular cross-section in the horizontal direction thereof and has a height in the up-down direction. The power module 500 may have an arbitrary shape that allows the power module 500 to be electrically conductive with the sensor module 200 and supply power thereto.

In the illustrated embodiment, the power module 500 includes a thermoelectric element 510, a heat dissipation member 520, and a power connector 530.

The thermoelectric element 510 is configured to produce power using a temperature difference between one side and the other side through the Peltier effect. The thermoelectric element 510 is electrically conductive with the conducting wire member 300 through the power connector 530. The power produced by the thermoelectric element 510 may be transmitted to the sensor module 200 through the conducting wire member 300.

The thermoelectric element 510 includes one surface coupled to a measurement target member and another surface opposite to the measurement target member. In the embodiment illustrated in FIG. 9, the one surface coupled to the measurement target member may be defined as an upper side surface, and the other surface opposite to the measurement target member may be defined as a lower side surface (that is, a surface coupled to the heat dissipation member 520).

A temperature of the measurement target member to which the one surface of the thermoelectric element 510 is coupled may be formed to be higher than a temperature of a space in which the other surface of the thermoelectric element 510 is located. The thermoelectric element 510 may produce power using the temperature difference. The power produced by the thermoelectric element 510 may be transmitted to the sensor module 200 through the power connector 530.

The heat dissipation member 520 is provided to maintain the other surface of the thermoelectric element 510 at a lower temperature, that is, increase the temperature difference between the one surface and the other surface.

The heat dissipation member 520 is coupled to the thermoelectric element 510 and configured to cool a surface of the thermoelectric element 510 that is in a specific direction. Accordingly, a temperature difference between the surface in the specific direction and another surface, among the surfaces of the thermoelectric element 510, may increase.

The heat dissipation member 520 may be coupled to the other surface opposite to the one surface coupled to the measurement target member among the surfaces of the thermoelectric element 510. Accordingly, the heat dissipation member 520 may cool the other surface and increase a temperature difference between the one surface and the other surface.

In the illustrated embodiment, the heat dissipation member 520 is coupled to the lower side surface of the thermoelectric element 510. In the embodiment, the upper side surface of the thermoelectric element 510 may be understood as being coupled to the measurement target member.

The heat dissipation member 520 may be provided in an arbitrary form that allows the heat dissipation member 520 to absorb and release heat from a component in contact therewith and cool the component. In the illustrated embodiment, the heat dissipation member 520 includes a plurality of fins and a plurality of spaces formed between the plurality of fins.

The power connector 530 is removably coupled to and electrically conductive with the sensor module 200. The power connector 530 may be coupled to and electrically conductive with the sensor module 200 due to the conducting wire member 300.

The power connector 530 may be disposed at an arbitrary position at which the power connector 530 can be coupled to and electrically conductive with the conducting wire member 300. In the illustrated embodiment, the power connector 530 is located at one surface, that is, the front side surface, of the thermoelectric element 510 that faces the sensor module 200.

In the embodiment, the power connector 530 may be coupled to and electrically conductive with a terminal (not illustrated) formed in the thermoelectric element 510. Accordingly, power produced by the thermoelectric element 510 may be transmitted to the sensor module 200 through the power connector 530.

The wireless sensor device 30 according to the present embodiment described above also includes the power module 500 and the sensor module 200 formed and disposed apart from each other physically. The power module 500 and the sensor module 200 may be electrically conductive with each other due to the conducting wire member 300, and power produced in the power module 500 may be transmitted to the sensor module 200.

Therefore, as compared to the case in which a component for power production and a component for detection are both provided in a single member, the size and weight of each of the modules 200 and 500 can be reduced.

Also, in the case of the present embodiment, produced power may increase with an increase in a temperature difference between a measurement target member and the outside. Therefore, various arrangement methods may be implemented. For example, the power module 500 may be placed at a point where the temperature is the highest, and only the sensor module 200 may be placed adjacent to a measurement target member.

Further, since the power module 500 and the sensor module 200 may be provided separately, when any one of the modules 200 and 500 is damaged, the wireless sensor device 30 may be continuously used after replacing only the corresponding module.

As a result, the durability and service life of the wireless sensor device 30 may be increased, and reliability of detected information may be improved. Further, since the degree of freedom of arrangement of the wireless sensor device 30 is improved due to the size reduction and modularization thereof, damage due to an external environment may also be prevented.

### 5. Description of Application Examples of Wireless Sensor Devices 10, 20, and 30 According to Various Embodiments of the Present Disclosure

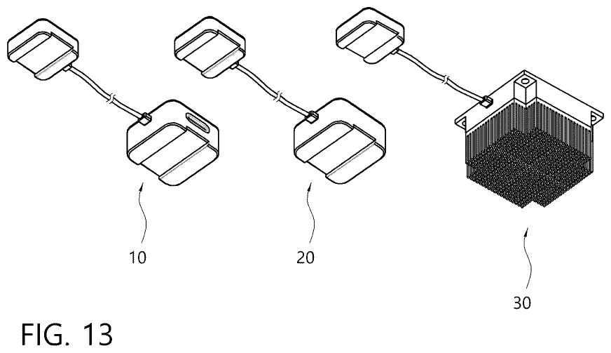

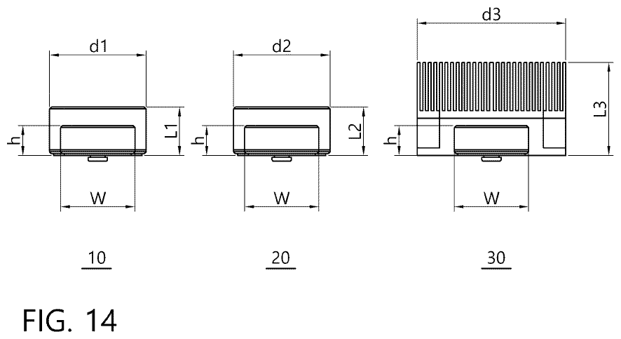

Referring to FIGS. 13 and 14, the wireless sensor devices 10, 20, and 30 according to different embodiments of the present disclosure are illustrated. In the wireless sensor devices 10, 20, and 30 according to different embodiments of the present disclosure described above, the power modules 100, 400, and 500 and the sensor module 200 are physically spaced apart and configured to be electrically conductive with each other.

Therefore, the power modules 100, 400, and 500 and the sensor module 200 may be disposed at different positions. Various effects according thereto are as described above.

Meanwhile, the wireless sensor devices 10, 20, and 30 according to different embodiments described above may be configured to generate or receive power in different forms and supply the power to the sensor module 200. To this end, the wireless sensor devices 10, 20, and 30 according to different embodiments described above may be formed to have different sizes.

Therefore, the wireless sensor devices 10, 20, and 30 according to different embodiments of the present disclosure may be selected in consideration of states of a measurement target member and the surrounding environment thereof, the broadness/narrowness of an installation space, and the like.

Hereinafter, application examples of the wireless sensor devices 10, 20, and 30 according to different embodiments of the present disclosure will be described with reference to FIGS. 13 and 14.

In the illustrated embodiment, it is assumed that the size of the sensor module 200 is the same. That is, as illustrated in FIG. 14, a length of the sensor module 200 in the left-right direction may be defined as a sensor width w, and a length of the sensor module 200 in the up-down direction may be defined as a sensor height h.

Therefore, it should be understood that the sizes of the power modules 100, 400, and 500 respectively provided in the wireless sensor devices 10, 20, and 30 according to different embodiments have a relatively greater influence on the sizes of the wireless sensor devices 10, 20, and 30 according to different embodiments.

First, the sizes of the wireless sensor device 10 according to one embodiment of the present disclosure and the wireless sensor device 20 according to another embodiment of the present disclosure may be relatively more reduced than the size of the wireless sensor device 30 according to still another embodiment of the present disclosure.

That is, as illustrated in FIG. 14, a first width d1 and a second width d2 which are maximum lengths of the wireless sensor devices 10 and 20 in the left-right direction are formed to be shorter than a third width d3 which is a maximum length of the wireless sensor device 30 in the same direction.

Likewise, a first length L1 and a second length L2 which are maximum lengths of the wireless sensor devices 10 and 20 in the height direction are formed to be shorter than a third length L3 which is a maximum length of the wireless sensor device 30 in the same direction.

Therefore, the wireless sensor device 10 according to one embodiment and the wireless sensor device 20 according to another embodiment may be more advantageous than the wireless sensor device 30 according to still another embodiment when an installation site is relatively narrow.

That is, the wireless sensor devices 10, 20, and 30 according to different embodiments of the present disclosure may be selected in consideration of the size of an installation space.

Of course, even in the above case, the sizes of the wireless sensor devices 10, 20, and 30 according to different embodiments may be more reduced compared to the case in which a member for detection and a member for supplying power are integrally formed. Therefore, it should be understood that the wireless sensor devices 10, 20, and 30 according to different embodiments may also be provided in an environment in which it is difficult to arrange a detection device as in the above case.

Also, in consideration of an installation environment, arranging the wireless sensor device 30 according to still another embodiment of the present disclosure may be more advantageous in an environment at a relatively high temperature. This is because, since the power module 500 provided in the wireless sensor device 30 according to the embodiment generates power using a temperature difference, power is more effectively generated in an environment of a high temperature.

On the other hand, in the environment of a relatively high temperature, it is difficult to arrange the wireless sensor device 20 according to another embodiment of the present disclosure. This is because the power module 400 provided in the wireless sensor device 20 according to the embodiment is provided in the form of a battery that can be charged and discharged repeatedly, and thus there is a risk of explosion or malfunction.

Further, in consideration of characteristics of a measurement target member, in the case of a member that carries alternating current, arranging the wireless sensor device 10 according to one embodiment of the present disclosure may be more advantageous. This is because, since the power module 100 provided in the wireless sensor device 10 according to the embodiment produces power using a change in a magnetic field, a change in the magnetic field due to alternating current can be effectively used.

Therefore, the wireless sensor devices 10, 20, and 30 according to various embodiments of the present disclosure described above may be selected and applied in various ways according to the environment for arrangement, space for arrangement, or characteristics of a measurement target member. Accordingly, desired information of a desired member can be accurately obtained, and damage to the wireless sensor devices 10, 20, and 30 can be prevented.

Meanwhile, the wireless sensor devices 10, 20, and 30 according to different embodiments described above may be selected according to various conditions described above.

That is, the power modules 100, 400, and 500 according to different embodiments are provided to be separable from the sensor module 200. Therefore, it should be understood that, when necessary, only the power modules 100, 400, and 500 may be replaced to configure the wireless sensor devices 10, 20, and 30 according to different embodiments.

Embodiments of the present disclosure have been described above, but the spirit of the present disclosure is not limited by the embodiments presented herein, and those of ordinary skill in the art who understand the spirit of the present disclosure may easily propose other embodiments by adding other components, changing components, or omitting components within the scope of the same spirit. However, such embodiments also belong to the scope of the spirit of the present disclosure.

| | |
|---|---|
| 10: wireless sensor device | 20: wireless sensor device |
| 30: wireless sensor device | 100: power module |
| 110: power housing | 111: power cover |
| 112: power space | 113: band coupling portion |
| 114: connector coupling portion | 115: tying space portion |
| 120: power PCB | 130: coil member |
| 140: power connector | 200: sensor module |
| 210: sensor housing | 211: sensor cover |
| 212: sensor space | 213: unit through-portion |
| 214: connector coupling portion | 215: tying space portion |
| 220: sensor PCB | 230: communication unit |
| 240: sensor unit | 250: sensor connector |
| 300: conducting wire member | 310: power connecting portion |
| 320: sensor connecting portion | 330: extending portion |
| 400: power module | 410: power housing |
| 411: power cover | 412: power space |
| 413: connector coupling portion | 414: tying space portion |
| 420: battery pack | 430: power connector |
| 500: power module | 510: thermoelectric element |
| 520: heat dissipation member | 530: power connector |
| w: sensor width | h: sensor height |
| d1: first width | d2: second width |
| d3: third width | L1: first length |
| L2: second length | L3: third length |

1. A wireless sensor device comprising:
a sensor module disposed adjacent to one portion of an external member and configured to detect information on a state of the external member;
a power module disposed adjacent to another portion of the external member to be physically spaced apart from the sensor module and configured to be electrically conductive with the sensor module to transmit power to the sensor module; and
a conducting wire member configured to be electrically conductive with each of the sensor module and the power module to transmit the power.

2. The wireless sensor device of claim 1, wherein the sensor module and the power module are removably coupled to each other.

3. The wireless sensor device of claim 1, wherein the power module includes a coil member configured to generate the power in a magnetic field energy harvesting manner using a change in a magnetic field formed therein.

4. The wireless sensor device of claim 3, wherein a band made of a ferromagnetic substance passes through the coil member.

5. The wireless sensor device of claim 3, wherein the power module includes:
a power housing in which a space accommodating the coil member is formed;
a power printed circuit board (PCB) accommodated in the space of the power housing and configured to be electrically conductive with the coil member; and
a power connector accommodated in the space of the power housing and configured to be electrically conductive with the power PCB, receive the power generated by the coil member, and be coupled to and electrically conductive with the conducting wire member to transmit the received power to the sensor module.

6. The wireless sensor device of claim 1, wherein the power module includes a battery pack configured to be charged by an external power source, store the power, and transmit the stored power to the sensor module.

7. The wireless sensor device of claim 6, wherein the power module includes:
a power housing in which a space accommodating the battery pack is formed; and
a power connector accommodated in the space of the power housing and configured to be electrically conductive with the battery pack, receive the power stored in the battery pack, and be coupled to and electrically conductive with the conducting wire member to transmit the received power to the sensor module.

8. The wireless sensor device of claim 7, wherein the battery pack is withdrawably accommodated in the space of the power housing.

9. The wireless sensor device of claim 1, wherein the power module includes a thermoelectric element configured to generate power using a temperature difference between the one portion of the external member and a space where the external member is located.

10. The wireless sensor device of claim 9, wherein the power module includes a heat dissipation member coupled to one surface facing the space where the external member is located among surfaces of the thermoelectric element and configured to cool the one surface of the thermoelectric element.

11. The wireless sensor device of claim 10, wherein the heat dissipation member includes a plurality of fins formed to extend in a direction opposite to the one surface of the thermoelectric element and a plurality of spaces formed by the plurality of fins being spaced apart from each other.

12. The wireless sensor device of claim 9, wherein the power module includes a power connector configured to be electrically conductive with the thermoelectric element, receive the power generated by the thermoelectric element, and be coupled to and electrically conductive with the conducting wire member to transmit the received power to the sensor module.

13. The wireless sensor device of claim 1, wherein the sensor module includes:
a sensor unit configured to detect information on a state of the one portion of the external member;
a communication unit configured to be electrically conductive with the sensor unit and transfer the detected information to an external terminal;
a sensor connector configured to be electrically conductive with the conducting wire member and receive the power; and
a sensor PCB configured to be electrically conductive with each of the sensor unit, the communication unit, and the sensor connector to transmit the power to the sensor unit and the communication unit.

14. The wireless sensor device of claim 1, wherein the conducting wire member includes:
a power connecting portion configured to be removably coupled to and electrically conductive with the power module;
a sensor connecting portion configured to be removably coupled to and electrically conductive with the sensor module; and
an extending portion extending between the power connecting portion and the sensor connecting portion and configured to be electrically conductive with each of the power connecting portion and the sensor connecting portion.

15. The wireless sensor device of claim 14, wherein the extending portion is formed of a flexible material.
